(19) United States
(12) Patent Application Publication
(10) Pub. No.: US 2014/0235007 A1
(43) Pub. Date: Aug. 21, 2014

(54) METHOD OF MANUFACTURING SEMICONDUCTOR LIGHT EMITTING DEVICE AND CHEMICAL VAPOR DEPOSITION APPARATUS

(71) Applicant: Samsung Electronics Co., Ltd., Suwon-si (KR)

(72) Inventors: Sang Heon HAN, Suwon-si (KR); Nam Sung KIM, Suwon-si (KR); Dong Joon KIM, Seoul (KR); Kong Tan SA, Seoul (KR); Tong Ik SHIN, Hwaseong-si (KR); Do Young RHEE, Seoul (KR); Jeong Wook LEE, Yongin-si (KR)

(73) Assignee: SAMSUNG ELECTRONICS CO., LTD., Suwon-si (KR)

(21) Appl. No.: 14/146,477

(22) Filed: Jan. 2, 2014

(30) Foreign Application Priority Data
Feb. 15, 2013 (KR) 10-2013-0016314

(51) Int. Cl. H01L 33/00; H01L 21/673

(52) U.S. Cl. CPC H01L 33/007; H01L 21/67326
USPC 438/46; 118/719

(57) ABSTRACT

A method of manufacturing a semiconductor light emitting device, includes sequentially growing a first conductivity-type semiconductor layer, an active layer, and a second conductivity-type semiconductor layer on a substrate to form a light emitting layer. The forming of the light emitting layer includes a first growth process, a second growth process and a transfer process. The first growth process uses a first susceptor having a mounting surface with a first curvature. The second growth process uses a second susceptor having a mounting surface with a second curvature different from the first curvature. The transfer process transfers the substrate from the first susceptor to the second susceptor between the first and second growth processes.

### CROSS-REFERENCE TO RELATED APPLICATION

This application claims benefit of the priority of Korean Patent Application No. 10-2013-0016314 filed on Feb. 15, 2013, in the Korean Intellectual Property Office, the entire contents of which are hereby incorporated by reference.

### TECHNICAL FIELD

The present inventive concept relates to a method of manufacturing a semiconductor light emitting device and a chemical vapor deposition apparatus used therefor.

### BACKGROUND

In general, a semiconductor device may be manufactured on a heterogeneous substrate by using a vapor deposition method (or a vapor growth method) such as metal organic vapor phase epitaxy (MOVPE), hydride vapor phase epitaxy (HVPE), or the like. For example, a nitride semiconductor device may be formed by growing a nitride single crystal on a heterogeneous substrate such as a sapphire (α-Al₂O₃) substrate or a SiC substrate.

However, such a heterogeneous substrate has a coefficient of thermal expansion different from a coefficient of thermal expansion of the nitride single crystal grown on an upper surface thereof, generating significant thermal stress according to a thickness of the single crystal film growth and a change in an ambient temperature, which causes the substrate to be bowed. As a result, the semiconductor device may be degraded. For example, in the case of a semiconductor light emitting device, an active layer grown on the bowed substrate may have a deviation in thicknesses between a central portion and a peripheral portion thereof, increasing wavelength dispersion.

A bowing problem in a substrate due to thermal stress during a growth process is a major obstacle to increasing a diameter of a wafer used as a substrate and is considered an obstacle in mass-producing semiconductor light emitting devices having an active layer.

### SUMMARY

An aspect of the present inventive concept relates to a novel method of manufacturing a semiconductor light emitting device and a vapor deposition apparatus capable of mitigating a bowing problem due to thermal stress in a growth process.

An aspect of the present inventive concept encompasses a method of manufacturing a semiconductor light emitting device. The method includes sequentially growing a first conductivity-type semiconductor layer, an active layer, and a second conductivity-type semiconductor layer on a substrate to form a light emitting layer. The forming of the light emitting layer includes a first growth process using a first susceptor having a mounting surface with a first curvature, a second growth process using a second susceptor having a mounting surface with a second curvature different from the first curvature, and a transfer process of transferring the substrate from the first susceptor to the second susceptor between the first and second growth processes.

The first and second growth processes may be performed in first and second process chambers, respectively, the first and second susceptors may be installed in the first and second process chambers, respectively, and the transfer process may include transferring the substrate from the first process chamber to the second process chamber while a controlled atmosphere is maintained.

The first and second growth processes may be performed in the same process chamber, and the method may further include replacing the first susceptor with the second susceptor within the process chamber, between the first and second growth processes.

The substrate may be formed of a material having a coefficient of thermal expansion higher than a coefficient of thermal expansion of a semiconductor constituting the light emitting layer, and the mounting surfaces of the first and second susceptors may have concave curved surfaces, respectively. The substrate may be a sapphire substrate and the light emitting layer may be formed of AlₓIn_{y}Ga_{1-x-y}N (here, 0≦x≦1, 0≦y≦1, 0≦x+y≦1).

The substrate may be formed of a material having a coefficient of thermal expansion lower than a coefficient of thermal expansion of the semiconductor constituting the light emitting layer, and the mounting surfaces of the first and second susceptors may have a convex curved surface. The substrate may be a silicon substrate, and the light emitting layer may be formed of AlₓIn_{y}Ga_{1-x-y}N (here, 0≦x≦1, 0≦y≦1, 0≦x+y≦1).

The forming of the light emitting layer may further include a third growth process using a third susceptor having a mounting surface with a third curvature different from the second curvature and an additional transfer process of transferring the substrate between at least one of the first and second susceptors and the third susceptor.

The first growth process may be a process of growing the first conductivity-type semiconductor layer, the second growth process may be a process of growing the active layer, and the third growth process may be a process of growing the second conductivity-type semiconductor layer.

The substrate may be a sapphire substrate, the light emitting layer may be formed of AlₓIn_{y}Ga_{1-x-y}N (here, 0≦x≦1, 0≦y≦1, 0≦x+y≦1), the mounting surfaces of the first to third susceptors may have concave curved surfaces, respectively, and the first curvature may be greater than the second and third curvatures and the second curvature may be smaller than the third curvature.

Another aspect of the present inventive concept relates to a vapor deposition apparatus including a first process chamber in which a first susceptor having a mounting surface with a first curvature is disposed, a second process chamber in which a second susceptor having a mounting surface with a second curvature different from the first curvature is disposed, and a substrate transfer robot configured to transfer a substrate between the first susceptor and the second susceptor, while maintaining a controlled atmosphere.

The first and second susceptor may have a plurality of substrate holders for mounting a plurality of substrates thereon, and lower surfaces of the plurality of substrate holders may be provided as the mounting surfaces.

The vapor deposition apparatus may further include a third chamber in which a third susceptor having a mounting surface with a third curvature different from the second curvature is disposed, and the substrate transfer robot may be configured to transfer a substrate between at least one of the first and second susceptors and the third susceptor.

The vapor deposition apparatus may further include a transfer chamber providing a space connecting the first, second, and third process chambers and having the substrate transfer robot disposed therein.

Still another aspect of the present inventive concept encompasses a vapor deposition apparatus including a process chamber in which a first susceptor having a mounting surface with a first curvature is disposed, a susceptor accommodating unit including a second susceptor that has a mounting surface with a second curvature different from the first curvature, and a transfer robot configured to replace the first susceptor with the second susceptor in the process chamber. The first susceptor is configured to be detachable from the process chamber.

The vapor deposition apparatus of claim may further include a transfer chamber connecting the process chamber and the susceptor accommodating unit.

The transfer robot may be disposed within the transfer chamber.

The susceptor accommodating unit may include a plurality of susceptors that have mounting surfaces with curvatures different from the first curvature.

The transfer robot may be configured to select one of the plurality of susceptors in the susceptor accommodating unit, and replace the first susceptor with the selected susceptor.

### BRIEF DESCRIPTION OF THE DRAWINGS

The above and other aspects, features and other advantages of the present inventive concept will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a flow chart illustrating a process of a method of manufacturing a semiconductor light emitting device according to an embodiment of the present inventive concept.

FIGS. 2A and 2B are flow charts illustrating a process for replacing a susceptor that may be employed for the method of manufacturing a semiconductor light emitting device according to an embodiment of the inventive concept.

FIGS. 3A and 3B are schematic views illustrating an example of a process replacing a susceptor when a substrate is bowed during an epitaxial growth process.

FIGS. 4A and 4B are schematic views illustrating another example of a process replacing a susceptor when a substrate is bowed during an epitaxial growth process.

FIGS. 5A and 5B are views illustrating various examples of a susceptor that may be employed in an embodiment of the present inventive concept.

FIG. 6 is a schematic view illustrating a vapor deposition apparatus according to a first embodiment of the present inventive concept.

FIG. 7 is a cross-sectional view illustrating an internal structure of a process chamber that may be employed in the vapor deposition apparatus illustrated in FIG. 6.

FIG. 8 is a schematic view illustrating a vapor deposition apparatus according to a second embodiment of the inventive concept.

FIG. 9 is a lateral sectional view of a nitride semiconductor light emitting device.

FIGS. 10A through 10C are schematic views illustrating an example of a process of replacing a susceptor according to a change in curvature of a substrate according to the first embodiment of the inventive concept.

FIG. 11 is a schematic view illustrating a modification of a vapor deposition apparatus according to the first embodiment of the inventive concept.

FIG. 12 is a schematic view illustrating another modification of a vapor deposition apparatus according to the first embodiment of the present inventive concept.

### DETAILED DESCRIPTION

Embodiments of the present inventive concept will now be described in detail with reference to the accompanying drawings.

The present inventive concept may, however, be embodied in many different forms and should not be construed as being limited to the embodiments set forth herein. Rather, these embodiments are provided so that this disclosure will be thorough and complete, and will fully convey the scope of the present inventive concept to those skilled in the art. In the drawings, the shapes and dimensions of elements may be exaggerated for clarity, and the same reference numerals will be used throughout to designate the same or like components.

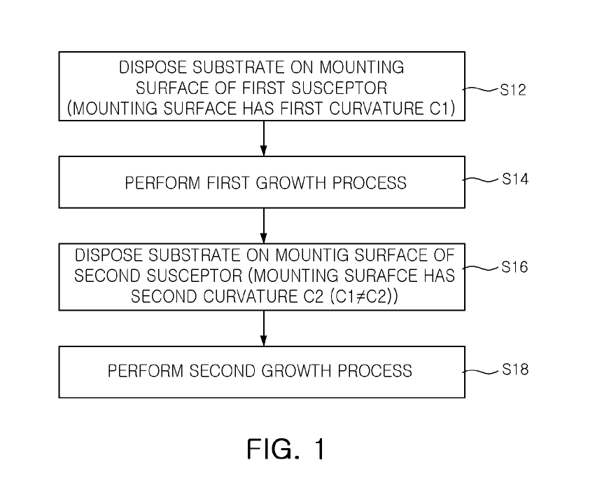

FIG. 1 is a flow chart illustrating a process of a method of manufacturing a semiconductor light emitting device according to an embodiment of the present inventive concept.

A method of manufacturing a semiconductor light emitting device according to an embodiment of the present inventive concept may include sequentially growing a first conductivity-type semiconductor layer, an active layer, and a second conductivity-type semiconductor layer on a substrate to form a light emitting layer. In the forming of the light emitting layer, the substrate may be bowed due to a difference in thermal stress between the grown epitaxial layer and the substrate, and a degree of bowing tends to vary according to a type, a thickness, and processing conditions (in particular, temperature conditions) of an epitaxial layer.

In an embodiment of the present inventive concept, growth may be temporarily stopped at a particular time at which the degree of bowing of the substrate is expected to be changed, and the substrate is re-disposed in a different susceptor prepared in consideration of an expected level of bowing.

In detail, as illustrated in FIG. 1, a substrate may be disposed on a mounting surface of a first susceptor in step S12. The mounting surface of the first susceptor has a first curvature C1. The substrate may be a substrate on which an epitaxial layer has not yet been grown or may be a substrate on which a portion of a desired epitaxial layer has already been grown.

Subsequently, a first growth process may be performed to grow an epitaxial layer on the substrate (S14). The first curvature may be determined in consideration of an expected degree of bowing of the substrate caused as the epitaxial layer is grown during the first growth process. Thus, although the degree of bowing of the substrate is changed during the first growth process, a relatively uniform space may be maintained between the substrate and the mounting surface of the first susceptor or a state in which the substrate is tightly attached to the mounting surface may be maintained.

Thereafter, the substrate positioned on the first susceptor may be transferred to be disposed on a mounting surface of a second susceptor in step S16. The mounting surface of the second susceptor has a second curvature C2 different from the first curvature C1. The substrate may be a substrate on which the epitaxial layer has been grown through the first growth process.

Thereafter, a second growth process may be performed to allow an epitaxial layer to be grown on the substrate by using the second susceptor (S18). The second curvature may be determined in consideration of an expected degree of bowing of the substrate caused according to the epitaxial layer grown during the second growth process. The degree of bowing of the substrate during the second growth process may be significantly different from the degree of bowing of the substrate during the first growth process due to various factors. Thus, when the second growth process is performed on the first susceptor, spaces between the substrate and the mounting surface of the susceptor in the centers and edges thereof may not be uneven to cause a significant difference between temperatures in various regions. As a result, epitaxial characteristics may differ in different region.

In order to mitigate the problem, a susceptor having a mounting surface with an appropriate degree of curvature may be provided in the second growth process. Thus, although a degree of bowing of the substrate during the second growth process is significantly different from a degree of bowing of the substrate during the first growth process, a relatively uniform space may be maintained between the substrate and the mounting surface of the second susceptor or the substrate may be maintained in a state of being tightly attached to the mounting surface of the second susceptor.

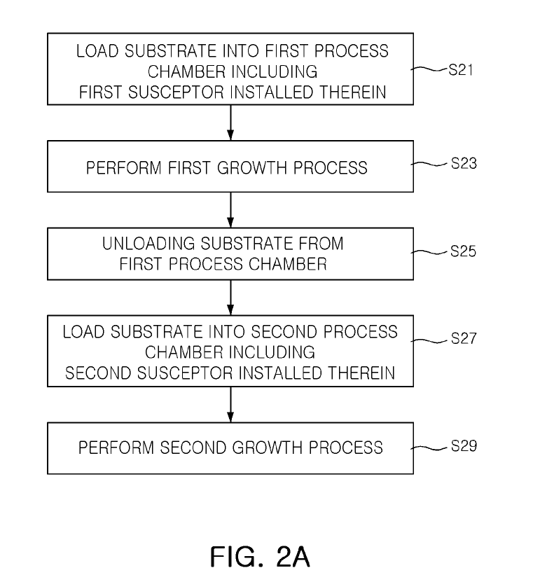

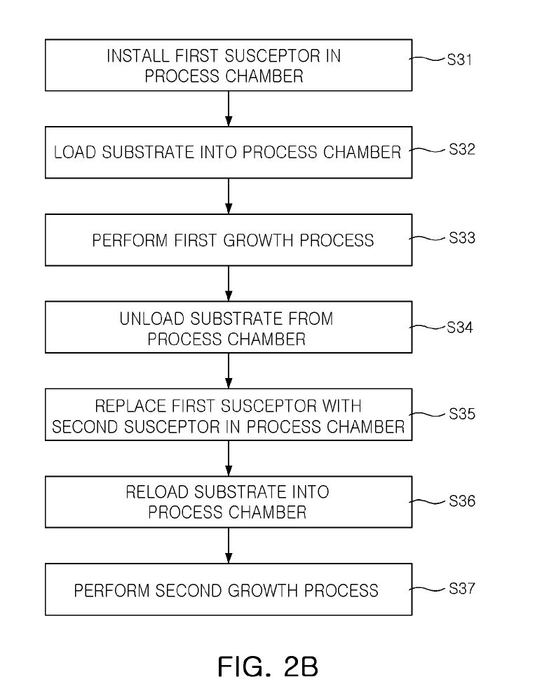

In order to perform the growth process by using a plurality of susceptors, the growth process may be temporarily stopped and the substrate may be transferred to a different susceptor. The substrate transferring process, namely, the susceptor changing process, may be performed in various manners, and as illustrated in FIGS. 2A and 2B, the substrate transferring process may be implemented by two types of methods.

In an example of the susceptor changing process illustrated in FIG. 2A, a divided growth process using a plurality of process chambers with susceptors under different conditions installed therein may be performed.

First, in operation S21, a substrate may be loaded in a first process chamber with a first susceptor installed therein. A mounting surface of the first susceptor has a first curvature C1 and this may be understood as a process corresponding to step S12. Namely, the substrate may be a substrate on which an epitaxial layer has not yet been grown or may be a substrate on which a portion of a desired epitaxial layer has been already grown.

Subsequently, a first growth process using the first susceptor may be performed (S23). The first curvature may be determined in consideration of an expected degree of bowing of the substrate caused as the epitaxial layer is grown during the first growth process.

Thereafter, the substrate with the epitaxial layer grown thereon may be unloaded from the first process chamber (S25), and the substrate may be loaded in a second process chamber with a second susceptor installed therein (S27). A mounting surface of the second susceptor may have a second curvature C2 different from the first curvature C1. Such a transfer process may be performed under a controlled atmosphere.

Subsequently, a second growth process using the second susceptor is performed (S29). The second curvature may also be determined in consideration of an expected degree of bowing of the substrate caused as an epitaxial layer is grown during the second growth process.

According to the divided growth process described here, the first and second process chambers may be provided, such that process conditions (source gas, temperature, pressure, and the like) are set for each process chamber based on a layer desired to be grown therein, and layers desired to be grown are divided into two groups to be grown in the first and second process chambers, respectively. The divided growth process provides advantages in that influence of the previous processing conditions remaining even after the process conditions are changed, as well as a time according to a change in the process conditions, may be reduced, thereby fundamentally resolving the bowing problem.

In the divided growth process, the mounting surfaces of the susceptors installed in the respective process chambers may be prepared to have different curvatures in consideration of an expected degree of bowing of the substrate according to the corresponding processes in advance, whereby the susceptor changing process can be naturally realized by performing the divided growth process without any other additional process.

In the foregoing divided growth process, the two-stage divided growth process using the first and second process chambers is illustrated, but the present inventive concept is not limited thereto and a multi-stage divided growth process using three or more process chambers may be implemented according to an amount of layers required for a semiconductor device, and even in this case, susceptors of the respective process chambers may be prepared to have mounting surfaces with different curvatures, whereby a space deviation between the substrate and the mounting surfaces according to a degree of bowing of the substrate caused during the respective growth processes is reduced and a temperature deviation (in particular, a difference in temperatures between the center and outer edges of the substrate) according to regions of the substrate can be effectively mitigated.

Unlike the process illustrated in FIG. 2A, in another example of the susceptor changing process, a susceptor used in a single process chamber may be replaced with a different susceptor.

Referring to FIG. 2B, a first susceptor may be installed in a process chamber in operation S31. A mounting surface of the first susceptor may have the first curvature C1, and the process chamber may be configured such that the susceptor is detachably replaced.

Subsequently, a substrate may be disposed on the mounting surface of the first susceptor (S32), and a first growth process may be performed (S33). Next, the substrate may be unloaded from the process chamber (S34), and the first susceptor may be replaced with a second susceptor in the process chamber (S35). As described above, the first and second susceptors have mounting surfaces having different curvatures. The substrate may be loaded into the process chamber with the second susceptor (S36) and a second growth process may be subsequently performed (s37).

In the example of process, it is illustrated in FIG. 2B that the susceptor changing process is performed after the substrate in the process chamber is removed, but the susceptor may be replaced when the substrate is held within the process chamber.

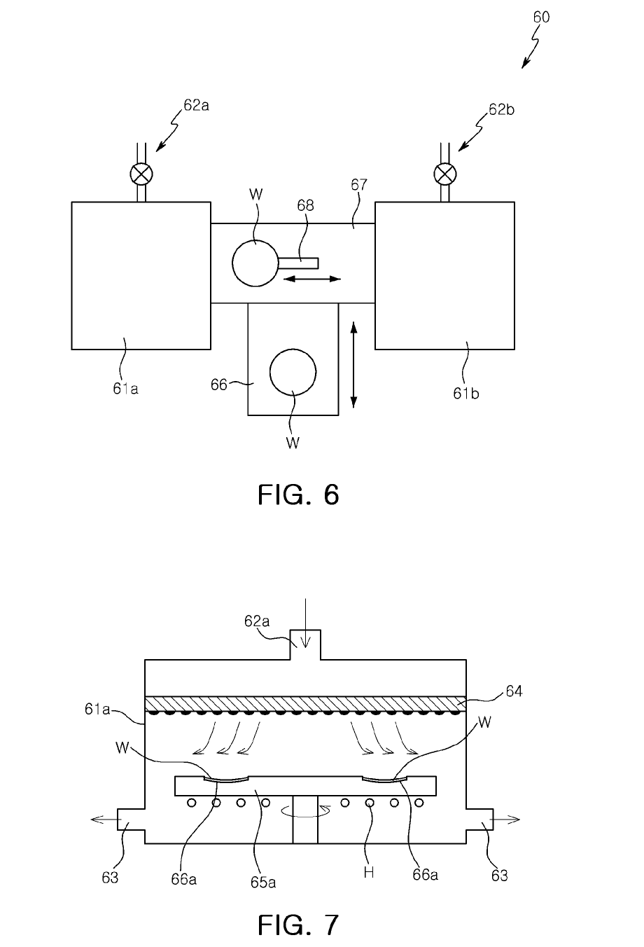

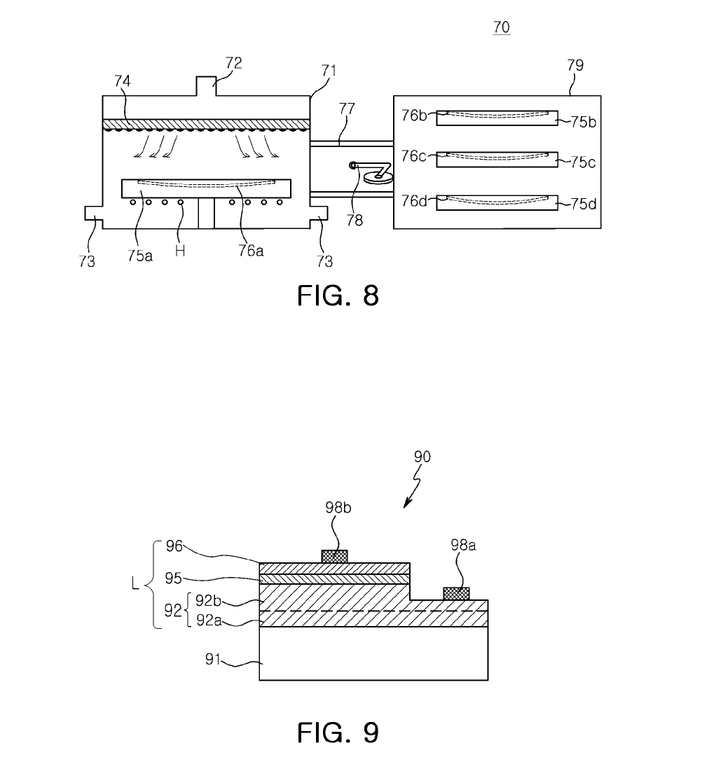

The two examples of the susceptor changing process, as illustrated in FIGS. 2A and 2B, may be implemented by a vapor deposition apparatus illustrated in FIGS. 6 and 8 and this will be described later. The two types of process examples may not necessarily be implemented independently and may be appropriately combined to be used. For example, in the divided growth process using the first and second process chambers including different susceptors, the first process chamber may be configured such that a susceptor having different curvature is additionally replaced.

In the process of forming a light emitting layer, a growth process may be performed by using a plurality of susceptors having mounting surfaces with different curvatures, and accordingly, heat may be transmitted to the entire surface of the substrate in a relatively uniform manner.

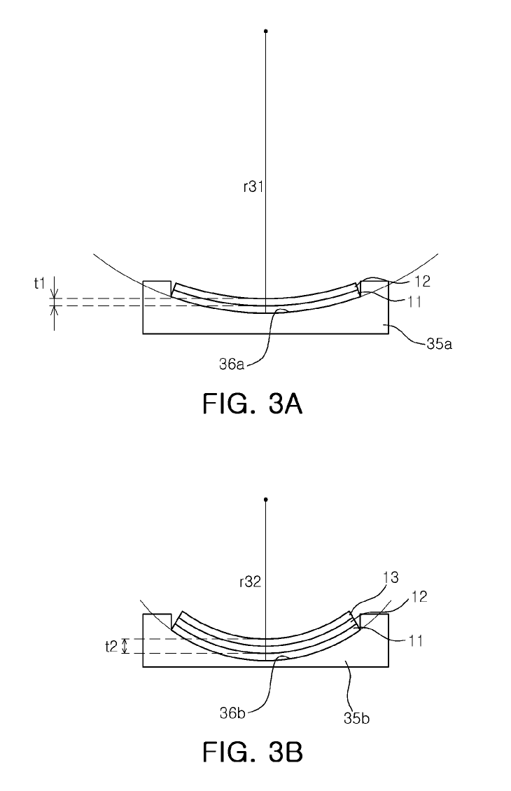

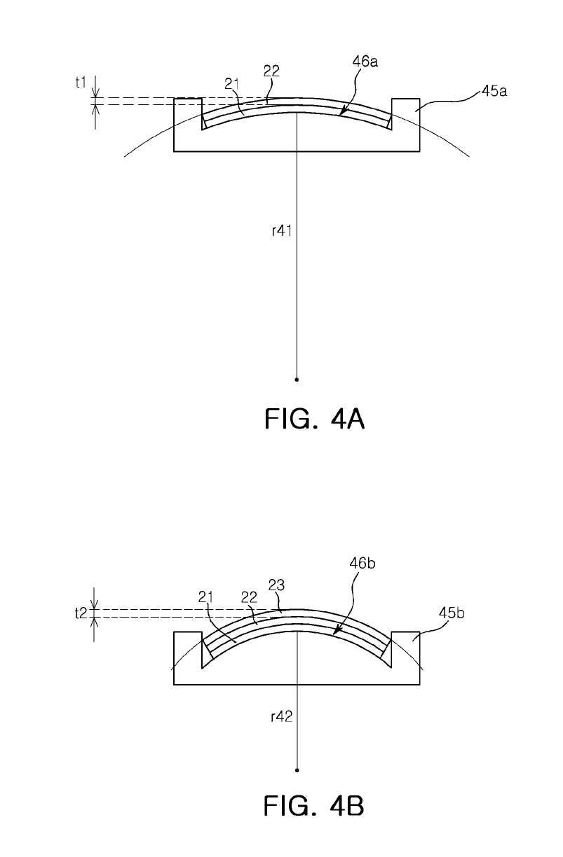

To this end, as described above, with respect to susceptors to be used for each process, a direction and a degree of bowing of the substrate in each process may be accurately estimated. A direction and a degree of bowing of the substrate may be determined based on a type of a substrate and an epitaxial layer (in particular, a coefficient of thermal expansion) to be grown, a process temperature, a growth thickness, and the like. FIGS. 3A, 3B, 4A and 4B are cross-sectional views illustrating examples of susceptors employed according to bowing of a substrate during an epitaxial growth process.

First, FIG. 3 illustrates a state of a first growth process when a substrate 11 is formed of a material having a coefficient of thermal expansion higher than a coefficient of thermal expansion of semiconductor layers 12 and 13 constituting a light emitting layer. In this example, the substrate 11 may be a sapphire substrate and the light emitting layer may be formed of AlₓIn_{y}Ga_{1-x-y}N (here, 0≦x≦1, 0≦y≦1, 0≦x+y≦1).

In this case, as illustrated in FIGS. 3A and 3B, the substrate 11 is bowed to have a downwardly concave surface, and accordingly, the mounting surfaces 36a and 36b of first and second susceptors 35a and 35b may have concave curved surfaces.

As illustrated in FIG. 3A, a first growth process may be performed on the first susceptor 35a having the mounting surface 36a with a first curvature radius r31. Since the first nitride semiconductor layer 12 having a first thickness t1 is formed on the sapphire substrate 11, thermal stress is generated to make the substrate 11 bowed to have a concave surface, and the mounting surface 36a of the first susceptor 35a may be prepared as a curved surface according to the degree of bowing. Thus, a state in which the substrate 11 is relatively uniformly tightly attached to the mounting surface 36a (or a state in which a space deviation is small) can be maintained.

Subsequently, as illustrated in FIG. 3B, when the second nitride semiconductor layer 13 is additionally formed on the first nitride semiconductor layer 12 during a second growth process, thermal stress may be generally increased as an overall thickness t2 of the nitride semiconductor layers is increased, and accordingly, strain may also be increased. Thus, in accordance with the degree of bowing, the second susceptor 35b may be prepared under the condition in which it has a second curvature radius r32, smaller than the first curvature radius r31, so that the substrate 11 can be maintained in a state of being relatively uniformly tightly attached to the mounting surface 36b (or in a state of having a small space deviation).

In a different particular example, as illustrated in FIGS. 4A and 4B, the substrate may have a coefficient of thermal expansion lower than a coefficient of thermal expansion of the semiconductor constituting the light emitting layer. For example, the substrate may be a silicon substrate and the light emitting layer may be formed of AlₓIn_{y}Ga_{1-x-y}N (here, 0≦x≦1, 0≦y≦1, 0≦x+y≦1). In this case, the substrate may be bowed to have an upwardly convex surface, and the mounting surfaces of the first and second susceptors may also have convex curved surfaces.

As illustrated in FIG. 4A, a first growth process may be performed on a first susceptor 45a having a mounting surface 46a with a first curvature radius r41. Since the first nitride semiconductor layer 22 having a first thickness t1 is formed on the sapphire substrate 21, thermal stress may be generated to make the substrate 21 bowed to have a convex surface, and the mounting surface 46a of the first susceptor 45a may be prepared as a curved surface according to the degree of bowing. Thus, a state in which the substrate 21 is relatively uniformly tightly attached to the mounting surface 46a (or a state in which a space deviation is small) can be maintained.

Subsequently, as illustrated in FIG. 4B, when the second nitride semiconductor layer 23 is additionally formed on the first nitride semiconductor layer 22 during a second growth process, thermal stress may be generally increased as an overall thickness t2 of the nitride semiconductor layers is increased, and accordingly, strain may also be increased. Thus, in accordance with the degree of bowing, the second susceptor 45b may be prepared under conditions in which it has a second curvature radius r42 smaller than the first curvature radius r41, so that the substrate 21 can be maintained in a state of being relatively uniformly tightly attached to the mounting surface 46b (or in a state of having a small space deviation).

In general, thermal stress is increased according to an increase in the thickness of an epitaxial layer, so strain thereof is also increased, but here, strain is not necessarily only determined by a growth thickness of an epitaxial layer. For example, when a growth temperature is lowered, strain is rather reduced although a growth thickness is increased, so, in this case, a susceptor having a curvature radius greater than a curvature radius of a previously used susceptor may be employed.

In this manner, by designing a curvature applied to a mounting surface of a susceptor according to a change in curvature of a substrate, a space between a surface of the substrate bowed during the growth process and the mounting surface of the susceptor can be minimized. Moreover, by implementing both the surface of the substrate and the mounting surface of the susceptor to be in contact, heat may be relatively uniformly transmitted across the entire surface of the substrate.

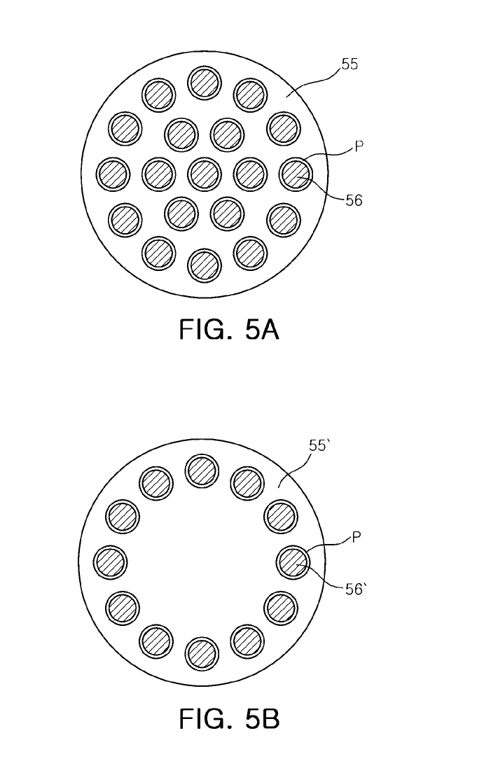

The susceptor may also be implemented to include a plurality of substrate holder units, instead of a single substrate, as illustrated in FIGS. 5A and 5B.

A susceptor 55, as illustrated in FIG. 5A, may include a plurality of substrate holder units P formed on the entire surface thereof. Lower surfaces of the respective substrate holder units P may be provided as mounting surfaces 56 having a predetermined curvature.

Unlike the susceptor 55, a susceptor 55′ illustrated in FIG. 5B may include a plurality of substrate holder units P arranged along an outer circumference thereof. Also, lower surfaces of the respective substrate holder units P may be provided as mounting surfaces 56′ having a predetermined curvature.

Hereinafter, an example of a vapor deposition apparatus capable of implementing a manufacturing method according to another aspect of the present inventive concept will be described. A vapor deposition apparatus illustrated in FIG. 6 is related to the susceptor changing method (the divided growth process) described above with reference to FIG. 2, and a vapor deposition apparatus illustrated in FIG. 8 is related to the susceptor changing method (the collective growth process) described above with reference to FIG. 3.

FIG. 6 is a schematic view of a vapor deposition apparatus according to a first embodiment of the present inventive concept.

A vapor deposition apparatus 60 according to an embodiment of the present inventive concept may include a first process chamber 61a, a second process chamber 61b, a transfer chamber 67 connecting the first process chamber 61a and the second process chamber 61b, and a transfer robot 68 installed within the transfer chamber to transfer a substrate W.

Gas injection units 62a and 62b for injecting a source gas for epitaxial growth may be formed in the first and second process chambers 61a and 61b, respectively. Both the first and second process chambers 61a and 61b may be deposition chambers using an organic metal gas, e.g., metal organic chemical vapor deposition (MOCVD) chambers. Alternatively, one of the process chambers may be a MOCVD chamber while the other may be a deposition chamber using a halide gas, e.g., a hydride vapor phase epitaxy (HVPE) chamber. Also, the first and second process chambers 61a and 61b may be any other deposition facilities, e.g., molecular beam epitaxy (MBE) chambers, rather than MOCVD or HVPE chambers.

The transfer chamber 67 may be configured to have an atmosphere controlled to allow the substrate W to be moved between the first and second process chambers 61a and 61b. For example, the transfer chamber 67 may accommodate the substrate W in a state in which an environment thereof is substantially the same as an internal environment or an external environment of the first and second process chambers 61a and 61b before the substrate W is loaded into the first and second process chambers 61a and 61b or before the substrate W is unloaded from the first and second process chambers 61a and 61b. To this end, the transfer chamber 67 may be maintained in a vacuum state.

Also, the transfer robot 68 installed within the transfer chamber 67 may be used as a means for inserting or removing the substrate W. A loading unit 66 may be configured to provide the substrate W to the vapor deposition apparatus 60.

A vapor deposition process, in particular, chemical vapor deposition (CVD), refers to a process of forming a non-volatile solid state film on a substrate by using reactions of gaseous chemical materials including required elements. The gaseous chemical materials are introduced into a reaction chamber and decomposed on the surface of the substrate heated to have a predetermined temperature so as to be reacted to form a semiconductor thin film. In this case, MOCVD uses an organic metal gas as a metal source gas for growing a thin film formed of a material such as a nitride semiconductor.

HVPE is a technique of injecting a halide gas such as hydrogen chloride into a reaction chamber to create a halide compound including a Group III element, supplying the halide compound to an upper portion of the substrate to allow the halide compound to react with a gas including a Group IV element to grow a semiconductor thin film.

Meanwhile, the MBE process, one of various compound semiconductor epitaxy methods, may be a process of forming a semiconductor thin film on a substrate maintained to have a high temperature by a molecular beam (or molecular line) or an atomic line having thermal energy.

The first and second process chambers 61a and 61b illustrated in FIG. 6 may be appropriately implemented to perform such a process, and commonly include a susceptor for disposing a substrate thereon, respectively. The susceptors provided in the first and second process chambers 61a and 61b have mounting surfaces having different curvatures. Curvature conditions with respect to the mounting surfaces of the respective susceptors may be implemented (or determined) in consideration of a direction and a degree of bowing anticipated during a growth process assigned to respective process chambers.

As a substantial example of a process chamber according to the present inventive concept, a first process chamber is illustrated in FIG. 7.

The first process chamber 61a may include the gas injection unit 62a disposed in an upper portion thereof, a gas distributer 64 uniformly dispersing an injected gas, and a gas exhaust unit 63. Also, the first process chamber 61a may further include a susceptor 65a allowing the substrate W to be mounted thereon and a heater unit H heating the substrate W disposed on the susceptor 65a. A mounting surface 66a employed in the susceptor 65a is illustrated to have a particular curvature. Although not shown, the susceptor installed in the second process chamber 61b may have a mounting surface having a curvature different from the particular curvature.

The first process chamber 61a may have a vertical chamber structure in which a source gas is injected from an upper portion of the substrate W, and may be understood to be an MOCVD process chamber. For example, in case of forming n-type GaN, TMGa, NH₃, and SiH₄ may be provided as source gases and a desired epitaxial layer may be grown through chemical decomposition and reaction at a high growth temperature (ranging about 900 to 1300° C.)

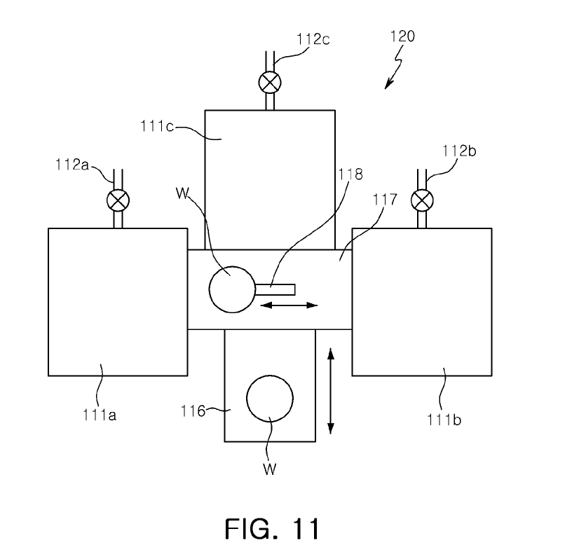

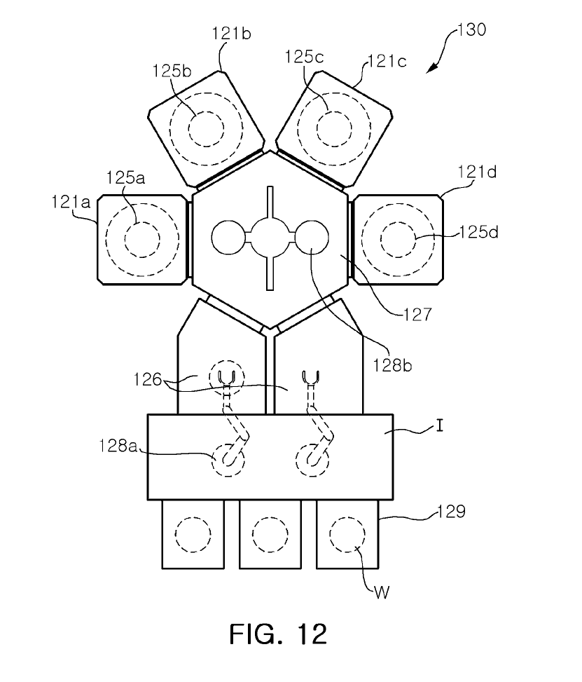

The vapor deposition apparatus of FIG. 6 is illustrated as having two process chambers for a divided growth process, but the amount of chambers may be increased according to a desired number of divided growth stages. An example thereof will be described later with reference to FIGS. 11 and 12.

A vapor deposition apparatus 70 illustrated in FIG. may include a process chamber 71, a susceptor accommodating unit 79, and a transfer chamber 77 connecting the process chamber 71 and the susceptor accommodating unit 79. The vapor deposition apparatus 70 according to an embodiment of the present inventive concept may include a transfer robot 78 installed within the transfer chamber 77 to transfer susceptors 75a to 75d.

The transfer chamber 77 may be configured to have an atmosphere controlled to allow the susceptors 75a to 75d to be moved. Although not shown, a load lock chamber and an additional transfer robot connected to the process chamber to install the substrate in the process chamber may be additionally provided.

Similar to the chamber illustrated in FIG. 7, the process chamber 71 illustrated in FIG. 8 may include a gas injection unit 72 injecting a source gas, a gas distributer 74 uniformly dispersing an injected gas, and a gas exhaust unit 73. Also, the process chamber 71 may further include a first susceptor 75a allowing the substrate W (not separately shown in FIG. 8) to be mounted thereon and a heater unit H heating the substrate W disposed on the susceptor 75a.

The first susceptor 75a installed in the process chamber 71 has a mounting surface 76a having a particular curvature. In an embodiment of the present inventive concept, the first susceptor 75a may be configured to be detachable with respect to the process chamber 71. According to each growth process, any one of the second to fourth susceptors 75b to 75d having mounting surfaces 76b to 75d having different curvatures disposed in the susceptor accommodating unit 79 may be selected, and the selected susceptor may be replaced with the susceptor 75a installed in the process chamber 71. The replacing process may be performed by the transfer robot 78.

In this manner, collective growth may be performed in the single process chamber 71, the growth process is stopped by process units in which degrees of bowing significantly differ, and a susceptor installed in the process chamber may be replaced with a different susceptor having an appropriate curvature.

The present inventive concept, in particular, performing of the divided growth process in combination may be advantageously applied to a semiconductor light emitting device in which layers have different compositions and growth conditions of the respective layers are different.

A change in bowing (curvature) of a substrate in each process, together with a structure and a growth process of a semiconductor light emitting device will be described.

First, as illustrated in FIG. 9, a semiconductor light emitting device 90 includes a substrate 91 and a light emitting layer L formed on the substrate 91. The light emitting layer L may include a first conductivity-type semiconductor layer 92, an active layer 95, and a second conductivity-type semiconductor layer 96.

The first conductivity-type semiconductor layer 92 may be grown on the substrate 91. The substrate W may be provided as a semiconductor growth substrate. For example, a substrate formed of a material such as SiC, MgAl₂O₄, MgO, LiAlO₂, LiGaO₂, GaN, or the like, may be used. In this case, sapphire is a crystal having Hexa-Rhombo R3c symmetry, of which lattice constants in c-axial and a-axial directions are approximately 13.001 Å and 4.758 Å, respectively, and has a C-plane (0001), an A-plane (1120), an R-plane (1102), and the like. In this case, a nitride thin film may be relatively easily grown on the C-plane of sapphire crystal, and because sapphire crystal is stable at high temperatures, a sapphire substrate is commonly used as a nitride growth substrate.

The first conductivity-type semiconductor layer 92 may be made of an n-type nitride semiconductor. For example, the first conductivity-type semiconductor layer 92 may be formed of AlₓIn_{y}Ga_{(1-x-y)}N (0≦x≦1, 0≦y≦1, 0≦x+y≦1) doped with silicon (Si), or the like. Alternatively, the first conductivity-type semiconductor layer 92 may be formed of AlₓIn_{y}Ga_{(1-x-y)}P (0≦x≦1, 0≦y≦1, 0≦x+y≦1). As illustrated in FIG. 9, the first conductivity-type semiconductor layer 92 employed in an embodiment of the present inventive concept may include undoped GaN 92a and n-type GaN 92b.

The second conductivity-type semiconductor layer 96 may be formed of a p-type nitride semiconductor, e.g., AlₓIn_{y}Ga_{(1-x-y)}N (0≦x≦1, 0≦y≦1, 0≦x+y≦1) or AlₓIn_{y}Ga_{(1-x-y)}P (0≦x≦1, 0≦y≦1, 0≦x+y≦1) doped with magnesium (Mg), or the like. The active layer 95 formed between the first and second conductivity-type semiconductor layers 92 and 96 emits light having a predetermined level of energy according to electron-hole recombination and may have a multi-quantum well (MQW) structure in which quantum well layers and quantum barrier layers are alternately laminated. Here, as the MQW structure, a multi-layer structure formed of AlₓIn_{y}Ga_{(1-x-y)}N (0≦x≦1, 0≦y≦1, 0≦x+y≦1), e.g., an InGaN/GaN structure, may be used. Alternatively, a multi-layer structure formed of AlₓIn_{y}Ga_{(1-x-y)}P (0≦x≦1, 0≦y≦1, 0≦x+y≦1), e.g., an InGaP/GaP structure, may be used and it may be more appropriate than a nitride semiconductor for emitting red light in terms of band gap energy characteristics of a material.

A change in curvature during a process of manufacturing a nitride semiconductor light emitting device using a sapphire substrate will be described as a typical example.

In detail, in case of growing a nitride semiconductor laminate for the structure illustrated in FIG. 9, a relatively great change in curvature may be made during a process of growing undoped GaN/n-type GaN. In general, an average curvature value in the process of growing updoped GaN/n-type GaN may be greater than an average curvature value in an MQW growth process and an average curvature value in a p-GaN growth process. The average curvature value in the MQW growth process may be smaller than an average curvature value in a p-GaN growth process.

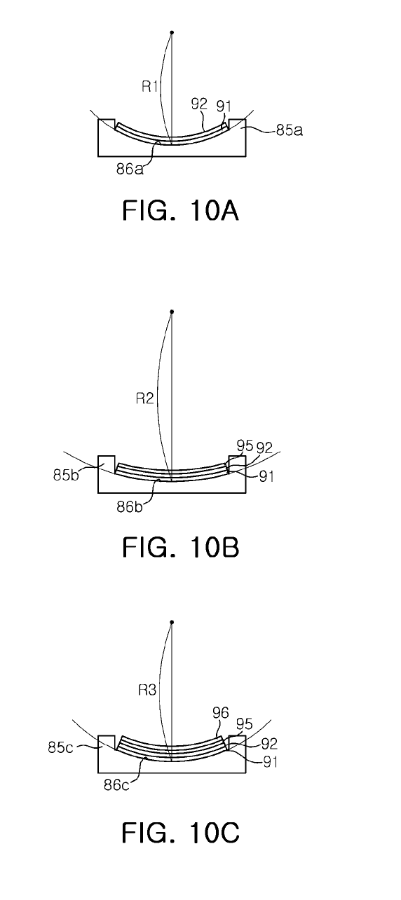

In consideration of such a change in curvature, a manufacturing process of the nitride semiconductor light emitting device may be divided into three sections, and mounting surfaces fitting a degree of bowing of a substrate may be provided by using susceptors (e.g., a total of three ones) having different curvature conditions in each divided process. FIGS. 10A to 10C illustrate examples of the susceptors.

First, referring to FIG. 10A, a first susceptor 85a used during a process of growing undoped GaN/n-type GaN 92 is illustrated. In this process, the substrate may have the greatest curvature, relative to other process, so the mounting surface 86a of the first susceptor 85a has the smallest first curvature radius R1.

As illustrated in FIG. 10B, a mounting surface 86b of a second susceptor 85b used during a process of growing MQW 95 may have a second curvature radius R2 greater than the first curvature radius R1. Also, as illustrated in FIG. 10C, a mounting surface 86c of a third susceptor 85c used during a process of growing p-type GaN 96 may have a third curvature radius R3 greater than the first curvature radius R1 but smaller than the second curvature radius R2.

In this manner, the first conductivity-type semiconductor layer/active layer/second conductivity-type semiconductor layer are dividedly grown in different process chambers in which susceptors having different curvatures are installed, providing many advantages. This will be described by referring to an example of a vapor deposition apparatus including three process chambers as illustrated in FIG. 11.

A vapor deposition apparatus 120 illustrated in FIG. 11 may include first, second, and third process chambers 111a, 111b, and 111c, a transfer chamber 117 connecting the first, second, and third process chambers 111a, 111b, and 111c, and a transfer robot 118 installed within the transfer chamber 117 to transfer the substrate W.

The first, second, and third process chambers 111a, 111b, and 111c may include gas injection units 112a, 112b, and 112c for injecting a source gas for epitaxial growth, respectively. The transfer chamber 117 may be configured to have an atmosphere controlled to allow the substrate W to be moved between the first, second, and third process chambers 111a, 111b, and 111c. Also, the transfer robot 118 may be installed in the transfer chamber 117 and used as a means for inserting or removing the substrate W. A loading unit 116 may be configured to provide the substrate W to the vapor deposition apparatus 120.

In an embodiment of the present inventive concept, the third process chamber 111c may be additionally provided, so the respective layers may be formed by using different process chambers. Namely, the first conductivity-type semiconductor layer may be grown in the first process chamber 111a, the active layer may be grown in the second process chamber 111b, and the second conductivity-type semiconductor layer may be grown in the third process chamber 111c. Also, the susceptors 85a, 85b, and 85c illustrated in FIGS. 10A to 10C may be employed in the respective process chamber to provide mounting surfaces having a curvature fitting a degree of bowing of the substrate according to each process, whereby a space between the substrate and the susceptors can be relatively uniformly maintained.

According to an embodiment of the present inventive concept, appropriate growth temperature conditions may be maintained in the first to third process chambers 111a to 111c, without being changed according to each stage. For example, the first process chamber 111a may be maintained at a temperature ranging from about 1100° C. to 1300° C. In order to grow an active layer having a InGaN/GaN quantum well structure, the second process chamber 111b may be maintained at a temperature ranging from about 700° C. to 900° C. When the second conductivity-type semiconductor layer is formed of, for example, p-type GaN, the third process chamber 111c may be maintained at a temperature ranging from about 900° C. to 1100° C.

In this manner, since the respective layers constituting the light emitting structure may be subdividedly grown, crystal quality can be further enhanced. Also, since different source gases, besides temperature conditions, are used in the respective chambers, a negative influence due to an undesired residual source can be prevented. For example, the interior of the first process chamber 111a may be maintained under, for example, an n-type doping element gas atmosphere. Similarly, the third process chamber 111c may be maintained under, for example, a p-type doping element gas atmosphere, having an advantage in that there is no need to change a doping element gas during a growth process.

As described above, the divided growth process using the vapor deposition apparatus illustrated in FIG. 11 may be implemented in three stages and the susceptors of the respective process chambers have mounting surfaces having different curvatures. Thus, a space deviation (in particular, a temperature difference between the center and the outer circumference) between the substrate and the mounting surfaces according to a degree of bowing of the substrate caused in each growth process can be effectively mitigated. Therefore, crystals having uniform characteristics can be grown on the regions of each substrate.

FIG. 12 is a view illustrating a modification of a vapor deposition apparatus according the first embodiment of the present inventive concept. Unlike the vapor deposition apparatus illustrated in FIG. 11, a vapor deposition apparatus 130 having four chambers and a different array structure is illustrated in FIG. 12.

The vapor deposition apparatus 130 illustrated in FIG. 12 includes first to fourth process chambers 121a, 121b, 121c, and 121d, a transfer chamber 127 connecting the first to fourth process chambers 121a, 121b, 121c, and 121d, and a loading unit 126 configured to load the substrate W. A substrate accommodating unit 129 may accommodate the substrate W and may be connected to the loading unit 126 through an interface unit I.

In an embodiment of the present inventive concept, a first transfer robot 128a may transfer the substrate W from the substrate accommodating unit 129 to the interior of the transfer chamber 127 through the loading unit 126. A second transfer robot 128b may be installed in the transfer chamber 127 and may mount the substrate W onto a desired reaction chamber 121a, 121b, 121c, or 121d or may transfer the substrate W to a different chamber.

The first, second, third, and fourth process chambers 121a, 121b, 121c, or 121d may employ susceptors 125a, 125b, 125c, and 125d having mounting surfaces with different curvatures. By providing mounting surfaces having curvatures fitting a degree of bowing of the substrate according to each process by using the susceptors 125a, 125b, 125c, and 125d, a space between the substrate and the susceptors can be relatively uniformly maintained.

Unlike the embodiment illustrated in FIG. 11 in which the light emitting structure is grown in three stages by using the three reaction chambers, in an embodiment of the present inventive concept, the respective layers are grown in four stages, so a susceptor appropriate for each condition can be employed, and thus, crystal quality can be further enhanced.

In an embodiment of the present inventive concept, the respective process chambers 121a, 121b, 121c, or 121d may further include a gas injection unit (not separately shown) for injecting a source gas for epitaxial growth and an exhaust unit (not separately shown).

In this manner, the growth process is divided in consideration of the features (e.g., a degree of bowing of a substrate) of each growth process, and each divided growth process may be realized by using susceptors having mounting surfaces with different curvatures in different chambers. Thus, a space deviation (in particular, a temperature difference between the center and the outer circumference) between the substrate and the mounting surfaces according to a degree of bowing of the substrate caused in each growth process can be effectively mitigated. As a result, crystals having uniform characteristics can be grown on the regions of each substrate.

As set forth above, according to embodiments of the invention, since a susceptor having a mounting surface with an appropriate curvature is used according to a degree of bowing of a substrate during an epitaxial growth process, non-uniformity of the characteristics of the substrate can be mitigated. In particular, serious non-uniform characteristics in case of using a wafer having a large diameter as a substrate can be effective mitigated.

Also, by performing the epitaxial divided growth process in combination, non-uniformity due to bowing of a substrate can be significantly improved without performing an additional process.

While the present inventive concept has been shown and described in connection with the embodiments, it will be apparent to those skilled in the art that modifications and variations can be made without departing from the spirit and scope of the invention as defined by the appended claims.

What is claimed is:

1. A method of manufacturing a semiconductor light emitting device, the method comprising:
sequentially growing a first conductivity-type semiconductor layer, an active layer, and a second conductivity-type semiconductor layer on a substrate to form a light emitting layer,
wherein the forming of the light emitting layer comprises a first growth process using a first susceptor having a mounting surface with a first curvature, a second growth process using a second susceptor having a mounting surface with a second curvature different from the first curvature, and a transfer process of transferring the substrate from the first susceptor to the second susceptor between the first and second growth processes.

2. The method of claim 1, wherein the first and second growth processes are performed in first and second process chambers, respectively, the first and second susceptors are installed in the first and second process chambers, respectively, and
the transfer process includes transferring the substrate from the first process chamber to the second process chamber while a controlled atmosphere is maintained.

3. The method of claim 1, wherein the first and second growth processes are performed in the same process chamber, and
the method further comprising replacing the first susceptor with the second susceptor within the process chamber, between the first and second growth processes.

4. The method of claim 1, wherein the substrate is formed of a material having a coefficient of thermal expansion higher than a coefficient of thermal expansion of a semiconductor constituting the light emitting layer, and
the mounting surfaces of the first and second susceptors have concave curved surfaces, respectively.

5. The method of claim 4, wherein:
the substrate is a sapphire substrate, and
the light emitting layer is formed of AlₓIn_{y}Ga_{1-x-y}N (here, 0≦x≦1, 0≦y≦1, 0≦x+y≦1).

6. The method of claim 1, wherein:
the substrate is formed of a material having a coefficient of thermal expansion lower than a coefficient of thermal expansion of the semiconductor constituting the light emitting layer, and
the mounting surfaces of the first and second susceptors have a convex curved surface.

7. The method of claim 6, wherein:
the substrate is a silicon substrate, and
the light emitting layer is formed of AlₓIn_{y}Ga_{1-x-y}N (here, 0≦x≦1, 0≦y≦1, 0≦x+y≦1).

8. The method of claim 1, wherein the forming of the light emitting layer further comprises:
a third growth process using a third susceptor having a mounting surface with a third curvature different from the second curvature; and
an additional transfer process of transferring the substrate between at least one of the first and second susceptors and the third susceptor.

9. The method of claim 8, wherein:
the first growth process is a process of growing the first conductivity-type semiconductor layer,
the second growth process is a process of growing the active layer, and
the third growth process is a process of growing the second conductivity-type semiconductor layer.

10. The method of claim 9, wherein:
the substrate is a sapphire substrate,
the light emitting layer is formed of AlₓIn_{y}Ga_{1-x-y}N (here, 0≦x≦1, 0≦y≦1, 0≦x+y≦1),
the mounting surfaces of the first to third susceptors have concave curved surfaces, respectively, and
the first curvature is greater than the second and third curvatures and the second curvature is smaller than the third curvature.

11. A vapor deposition apparatus, comprising:
a first process chamber in which a first susceptor having a mounting surface with a first curvature is disposed;
a second process chamber in which a second susceptor having a mounting surface with a second curvature different from the first curvature is disposed; and
a substrate transfer robot configured to transfer a substrate between the first susceptor and the second susceptor, while maintaining a controlled atmosphere.

12. The vapor deposition apparatus of claim 11, wherein:
the first and second susceptor have a plurality of substrate holders for mounting a plurality of substrates thereon, and
lower surfaces of the plurality of substrate holders are provided as the mounting surfaces.

13. The vapor deposition apparatus of claim 11, further comprising: a third chamber in which a third susceptor having a mounting surface with a third curvature different from the second curvature is disposed, and
the substrate transfer robot is configured to transfer a substrate between at least one of the first and second susceptors and the third susceptor.

14. The vapor deposition apparatus of claim 13, further comprising a transfer chamber providing a space connecting the first, second, and third process chambers and having the substrate transfer robot disposed therein.

15. The vapor deposition apparatus of claim 13, wherein:
the mounting surfaces of the first to third susceptors have concave curved surfaces, respectively, and
the first curvature is greater than the second and third curvatures and the second curvature is smaller than the third curvature.

16. A vapor deposition apparatus, comprising:
a process chamber in which a first susceptor having a mounting surface with a first curvature is disposed, the first susceptor being configured to be detachable from the process chamber;
a susceptor accommodating unit including a second susceptor that has a mounting surface with a second curvature different from the first curvature; and
a transfer robot configured to replace the first susceptor with the second susceptor in the process chamber.

17. The vapor deposition apparatus of claim 16, further comprising a transfer chamber connecting the process chamber and the susceptor accommodating unit.

18. The vapor deposition apparatus of claim 17, wherein the transfer robot is disposed within the transfer chamber.

19. The vapor deposition apparatus of claim 16, wherein the susceptor accommodating unit includes a plurality of susceptors that have mounting surfaces with curvatures different from the first curvature.

20. The vapor deposition apparatus of claim 19, wherein the transfer robot is configured to select one of the plurality of susceptors in the susceptor accommodating unit, and replace the first susceptor with the selected susceptor.
